(19) United States
(12) Patent Application Publication
(10) Pub. No.: US 2016/0049509 A1
(43) Pub. Date: Feb. 18, 2016

(54) SEMICONDUCTOR DEVICE

(71) Applicant: KABUSHIKI KAISHA TOSHIBA, Tokyo (JP)

(72) Inventor: Shigeki TOMITA, Kawasaki Kanagawa (JP)

(21) Appl. No.: 14/633,070

(22) Filed: Feb. 26, 2015

(30) Foreign Application Priority Data
Aug. 13, 2014 (JP) 2014-164683

(51) Int. Cl. H01L 29/78; H01L 29/423; H01L 21/311; H01L 21/28; H01L 21/768; H01L 29/66; H01L 21/308

(52) U.S. Cl. CPC H01L 29/7813; H01L 29/66734; H01L 29/4236; H01L 29/42376; H01L 21/308; H01L 21/28026; H01L 21/76802; H01L 21/76877; H01L 21/31111

(57) ABSTRACT

A semiconductor device includes a semiconductor layer having a first surface and a second surface opposed to the first surface, a control electrode provided on the second surface side of the semiconductor layer, and a conductor provided on the second surface which is electrically connected to the control electrode. The conductor includes a first portion provided on the second surface, and at least one second portion reaching from the first portion into the semiconductor layer.

### CROSS-REFERENCE TO RELATED APPLICATION

This application is based upon and claims the benefit of priority from Japanese Patent Application No. 2014-164683, filed Aug. 13, 2014, the entire contents of which are incorporated herein by reference.

### FIELD

Embodiments relate to a semiconductor device.

### BACKGROUND

In response to the desire for efficient power usage, for saving energy and the like, the on-resistance of a semiconductor device for power control and the like is required to be reduced. The on-resistance of a semiconductor device may be reduced by increasing the area of the element formation region on a chip and thereby spaces the gate electrodes, etc., further apart, but the size of the chip increases. Some semiconductor devices have wiring which is electrically connected to a control electrode, for example. For such a semiconductor device, it is possible to lower the on-resistance by reducing a wiring region to increase the area of the element region. However, reducing the wiring region sometimes results in an increase in the resistance of the wiring because the cross section of the wiring is resultantly lowered.

### DESCRIPTION OF THE DRAWINGS

FIG. 1 is schematic cross-sectional view illustrating a semiconductor device according to an embodiment.

FIGS. 2A to 2C are schematic cross-sectional views illustrating the manufacturing process of the semiconductor device according to the embodiment.

FIGS. 3A to 3C are schematic cross-sectional views illustrating the manufacturing process subsequent to FIGS. 2A to 2C.

FIGS. 4A to 4C are schematic cross-sectional views illustrating the manufacturing process subsequent to FIGS. 3A to 3C.

FIGS. 5A to 5C are plane views illustrating a mask pattern used to form a trench.

### DETAILED DESCRIPTION

In general, according to one embodiment, a semiconductor device includes a semiconductor layer having a first surface and a second surface opposed to the first surface, a control electrode provided on the second surface side of the semiconductor layer, and a conductor provided on the second surface which is electrically connected to the control electrode. The conductor includes a first portion provided on the second surface, and at least one second portion reaching from the first portion into the semiconductor layer.

Embodiments will be described below with reference to the accompanying drawings. The same reference numbers and symbols are assigned to the same elements shown in the drawings and a detailed description thereof in later drawings is omitted as appropriate. Note that the drawings are schematic or conceptual and relationship of the thickness and width of each portion, and the size ratio between portions are not necessarily the same as an actual device. Further, even if the same portions are illustrated in different drawings, respective dimensions and ratios thereof are sometimes differently illustrated in respective drawings.

Further, the placement and configuration of each portion will be described using an X-axis, a Y-axis and a Z-axis illustrated in each drawing. The X-axis, Y-axis and Z-axis are mutually orthogonal, and represent the X direction, Y direction and Z direction, respectively. Furthermore, the description may be provided by assuming that the Z direction represents an upper direction as described herein and the opposite direction thereto represents a lower direction as described herein.

Hereinafter, the description will be given in which a first conductivity type is an n-type and a second conductivity type is a p-type. However, the first conductivity type maybe a p-type and a second conductivity type may be an n-type.

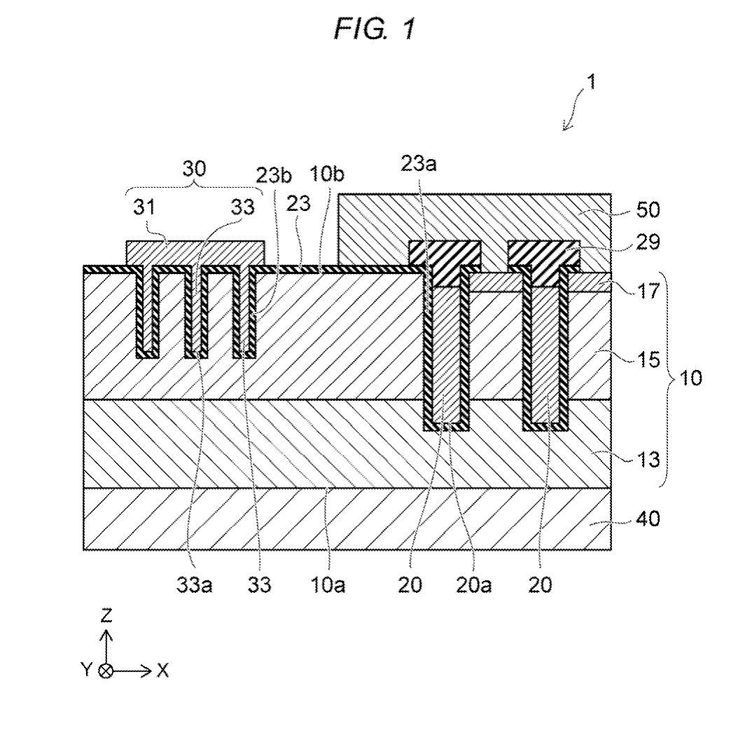

FIG. 1 is schematic cross-sectional view illustrating a semiconductor device 1 according to an embodiment. For example, the semiconductor device 1 is a power MOSFET (Metal Oxide Semiconductor Field Effect Transistor) having a trench gate structure. Note that the embodiment is not limited to a MOSFET having a trench gate structure, and, for example, an MOSFET having a planar gate structure may be used.

The semiconductor device 1 includes a semiconductor layer 10, a control electrode (hereinafter, referred to as a gate electrode 20) and wiring in the form of a conductor (hereinafter, referred to as a gate wiring 30). For example, the semiconductor layer 10 has a first surface 10a and a second surface 10b opposed to the first surface 10a. The gate electrode 20 is provided on the second surface 10b side of the semiconductor layer 10. The gate wiring 30 is provided on the second surface 10b.

For example, the semiconductor layer 10 includes a first layer (hereinafter, referred to as an n-type drain layer 13) and a second layer (hereinafter, referred to as a p-type base layer 15). A p-type base layer 15 is provided on the n-type drain layer 13. The n-type drain layer 13 has the first surface 10a. The p-type base layer 15 has the second surface 10b.

The gate electrode 20 extends through the p-type base layer 15 and into the n-type drain layer 13 over an insulating layer coating a trench structure extending through the p-type base layer 15 and into the n-type drain layer 13. For example, the gate electrode 20 extends toward the n-type drain layer 13 from the p-type base layer 15. The lower end 20a of the gate electrode 20 is located within the n-type drain layer 13. In this example, more than one gate electrode 20 is provided.

Further, the semiconductor layer 10 includes a third layer (hereinafter, referred to as an n-type source layer 17). The n-type source layer 17 is selectively provided on the p-type base layer 15. The n-type source layer 17 is provided on the second surface 10b of the semiconductor layer 10 between adjacent, in a first direction (hereinafter, referred to as an X direction), gate electrodes 20.

The gate wiring 30 includes a first portion 31 and a second portion 33. The first portion 31 is provided on the second surface 10b. The second portion 33 extends inwardly of the semiconductor layer 10 from the first portion 31. For example, the second portion 33 extends inwardly of the p-type base layer 15 toward the n-type drain layer 13 in trenches lined with an insulating layer. The lower end 33a of the second portion 33 terminates within the 15 p-type base layer.

The gate wiring 30 is electrically connected to the gate electrode 20 in a portion of the device which is not illustrated. For example, the gate wiring 30 is a conductor which electrically connects a plurality of gate electrodes 20 together.

Further, the semiconductor device 1 includes an insulating film 23 (a dielectric film), an interlayer insulating film 29, a first electrode (hereinafter, referred to as a drain electrode 40), and a second electrode (hereinafter, referred to as a source electrode 50).

The insulating film 23 covers the second surface 10b side of the semiconductor layer 10. The insulating film 23 includes a first portion 23a extending inwardly of the gate trenches and is provided between the gate electrode 20 and the adjacent portions of the semiconductor layer 10. The first portion 23a serves as agate insulating film. The insulating film 23 includes a second portion 23b extending inwardly of the wiring trenches and is provided between the gate wiring 30 and the second surface 10b and between the portions of the wiring 33 extending inwardly of the wiring trenches and the adjacent portions of the semiconductor layer 10.

The interlayer insulating film 29 is provided on each gate electrode 20.

The drain electrode 40 is provided on the first surface 10a side of the semiconductor layer 10. The drain electrode 40 is electrically connected to the semiconductor layer 10. For example, the drain electrode 40 is in contact with the n-type drain layer 13.

The source electrode 50 is selectively provided on the second surface 10b side of the semiconductor layer. For example, the source electrode 50 covers the interlayer insulating film 29 and the n-type source layer 17. The source electrode 50 is electrically connected to the n-type source layer 17.

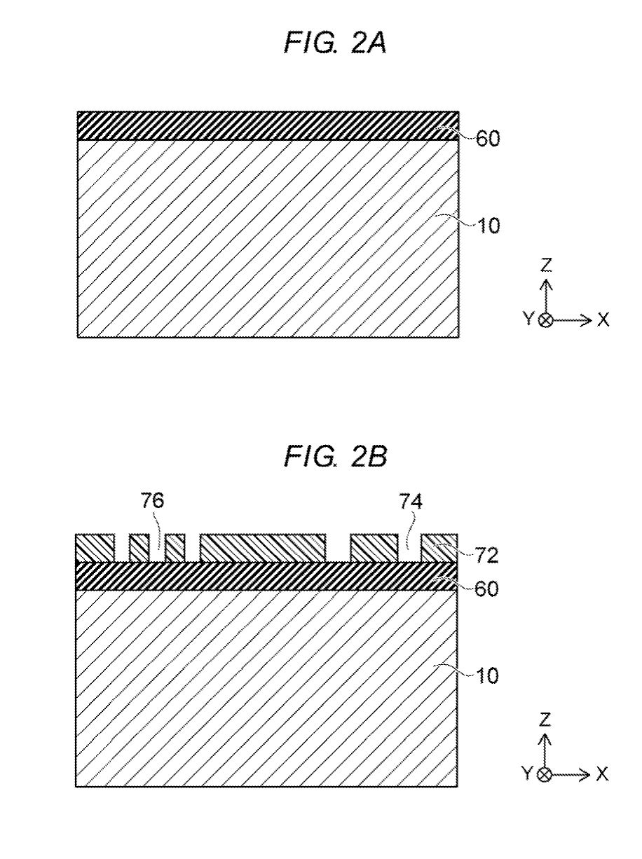

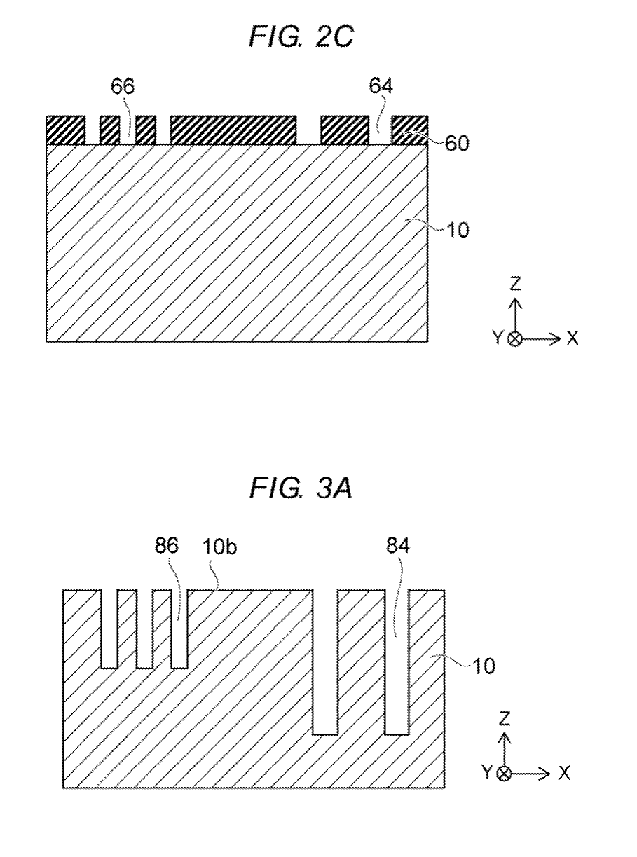

FIGS. 2 to 4 are schematic cross-sectional views illustrating the manufacturing process of the semiconductor device 1 according to the embodiment.

As illustrated in FIG. 2A, an insulating film 60 is formed on the semiconductor layer 10. For example, the semiconductor layer 10 is a silicon layer provided on a silicon substrate. The semiconductor layer 10 may also be a silicon substrate. The insulating film 60 is a silicon oxide film (SiO₂), for example.

As illustrated in FIG. 2B, a resist film 72 is formed on the insulating film 60. The resist film 72 formed on the insulating film 60 is patterned by photolithography to form grooves 74 and grooves 76 therein. Each of the grooves 74 and 76 is open at the base thereof to expose the insulating film 60 therein. For example, each of the grooves 74 and 76 extends in a second direction (hereinafter, referred to as a Y direction) parallel to the second surface 10b and perpendicular to the X direction. The width in the X direction of the groove 74 is wider than the width in the X direction of the groove 76.

As illustrated in FIG. 2C, by etching through the patterned resist layer 72, a groove 64 and a groove 66 are formed in the insulating film 60. Then, the resist film 72 is removed. Each of the grooves 64 and 66 is open at its base to expose the semiconductor layer 10 therein. For example, each of the grooves 64 and 66 extends in the Y direction. The width in the X direction of the groove 64 is wider than the width in the X direction of the groove 66.

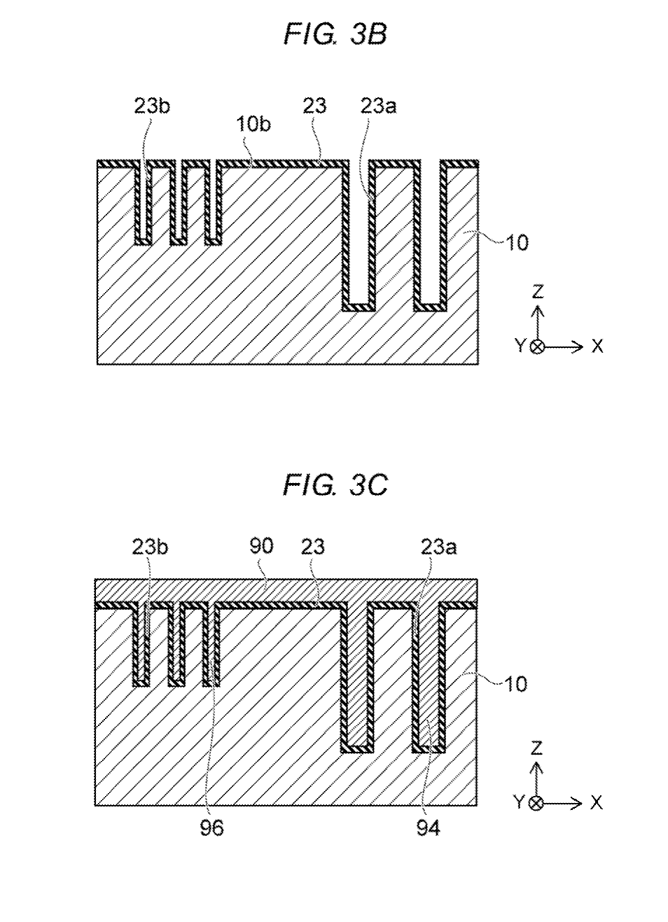

As illustrated in FIG. 3A, a trench 84 and a trench 86 are formed on the side of the second surface 10b of the semiconductor layer 10. The insulating film 60 in which the grooves 64 and 66 are provided serves as a hard mask, and the trenches 84 and 86 are formed by selectively etching the semiconductor layer 10 using RIE (Reactive Ion Etching), for example. Here, it is assumed that the direction which is perpendicular to the second surface 10b and extending from the first surface 10a to the second surface 10b is a third direction (hereinafter, referred to as a Z direction). Further, it is assumed that the direction opposite to the third direction is a −Z direction.

The depth of the −Z direction of the trench 84 is deeper than the depth of the −Z direction of the trench 86. This is because of a micro-loading effect occurring during etching. For example, when grooves of different widths are simultaneously etched into the semiconductor layer 10, the etching rate of the underlying layer being etched in the wider groove is faster than the etching rate in the narrower groove, because reactive etch species are more readily (and rapidly) replaced in a wider as opposed to narrower feature. That is, the etching rate in the −Z direction of the semiconductor layer 10 in communication with the groove 64 having the wider width in the X direction is faster than the etching rate in the −Z direction of the semiconductor layer 10 in communication with the groove 66 having the narrower width in the X direction.

As illustrated in FIG. 3B, an insulating film 23 is formed to cover the second surface 10b side of the semiconductor layer 10. The insulating film 23 includes a first portion 23a formed on the inner surface of the trenches 84, and a second portion 23b formed on the inner surface of the trench 86. The insulating film 23 is a silicon oxide film (SiO₂), for example. The insulating film 23 is formed by thermal oxidation, by heating the semiconductor layer 10 and exposing the heated semiconductor layer 10 to oxygen and thus cause a surface reaction to form silicon oxide, for example.

As illustrated in FIG. 3C, a polysilicon layer 90 is formed on the insulating film 23. The polysilicon layer 90 also includes a first portion 94 and a second portion 96. The first portion 94 extends in the −Z direction, and inwardly of the semiconductor layer 10 to be embedded in the trench 84 over the first portion 23a of the insulating film 23. The second portion 96 extends in the −Z direction and inwardly of the semiconductor layer 10 to be embedded in the trench 86 over the second portion 23b of the insulating film 23. The first portion 94 will form the gate electrode 20. The second portion 96 will form the second portion 33 of the gate wiring 30. The polysilicon layer 90 is formed using CVD (Chemical Vapor Deposition), for example.

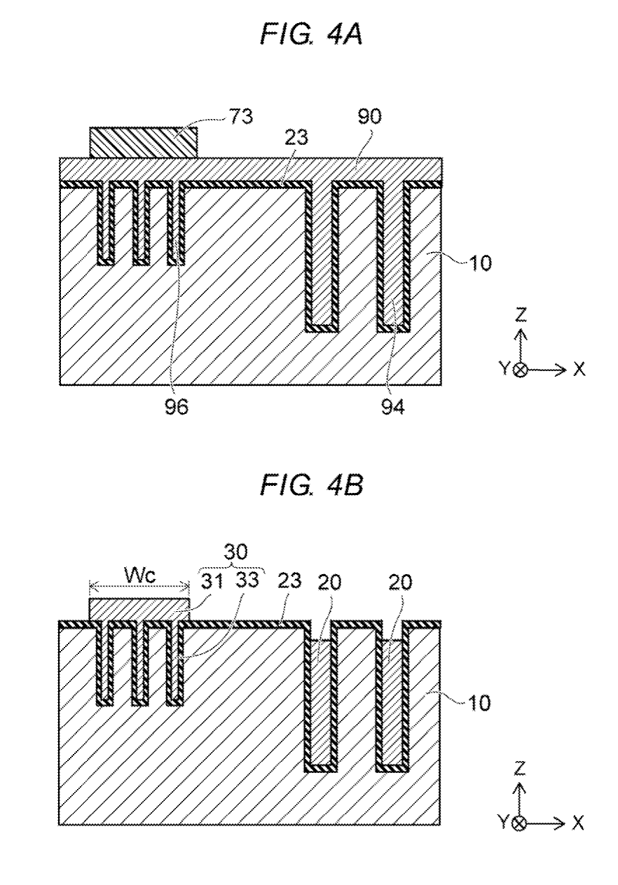

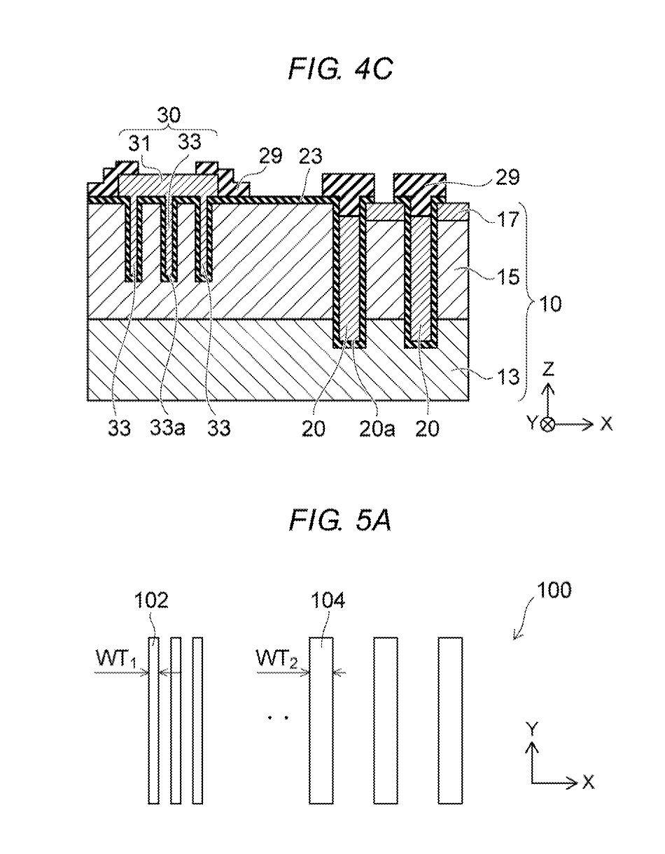

As illustrated in FIG. 4A, a patterned resist film 73 is photo lithographically formed on the polysilicon layer 90. The resist film 73 covers the portion of the polysilicon which will form the first portion 31 of the gate wiring 30.

As illustrated in FIG. 4B, the gate electrode 20 and the gate wiring 30 are isolated from the continuous polysilicon layer 90 by the etching thereof. With the resist film 73 serving as a mask, the gate electrode 20 and the gate wiring 30 are formed therefrom by selectively etching the polysilicon layer 90. The gate electrode 20 is formed by leaving the first portion 94 of the polysilicon layer 90 in the trenches. Thereafter, the resist film 73 is removed.

By this etching, the gate electrode 20 and the gate wiring 30 may be formed simultaneously. The polysilicon layer 90 is etched using CDE (Chemical Dry Etching), for example.

As illustrated in FIG. 4C, the p-type base layer 15, the n-type source layer 17 and the interlayer insulating film 29 are now formed. The p-type base layer 15 is formed by implanting boron (B) ions into the semiconductor layer 10, followed by heat treatment to diffuse the boron (B), for example. The boron (B) is implanted into the second surface 10b side of the semiconductor layer 10.

The p-type base layer 15 is shallower than the location of the lower end 20a of the gate electrode 20 inwardly of the second side 10b of the semiconductor layer 10 in the −Z direction. The p-type base layer 15 is deeper than the lower end 33a of the second portion 33 of the gate wiring 30 inwardly of the second side 10b of the semiconductor layer 10 in the −Z direction. This structure can prevent parasitic capacitance from being generated between the second portion 33 and the drain electrode 40. That is, this can prevent increases in gate-drain capacitance.

The n-type source layer 17 is formed on the p-type base layer 15. The n-type source layer 17 is formed by selectively implanting arsenic (As) ions into the semiconductor layer 10, for example. The arsenic (As) ion is implanted into the second surface 10b side of the semiconductor layer 10. The n-type source layer 17 is provided between adjacent, in the X-direction, gate electrodes 20.

The interlayer insulating film 29 is next formed to cover the gate electrodes 20. The interlayer insulating film 29 is also formed to cover the sides of the gate wiring 30. The interlayer insulating film 29 is a silicon oxide film (SiO₂), for example. The interlayer insulating film 29 is formed by a CVD process, for example.

The source electrode 50 is now formed to cover the interlayer insulating film 29 and the n-type source layer 17 (FIG. 1). The source electrode 50 is electrically connected to the n-type source layer 17. The drain electrode 40 is now formed on the first surface 10a side of the semiconductor layer 10. The drain electrode 40 is electrically connected to the semiconductor layer 10. By the manufacturing process described above, the semiconductor device 1 may be completed.

Next, the shape of the second portion 33 of the gate wiring 30 will be described. The second portion 33 of the gate wiring 30 is embedded in the trench 86 and over the second portion 23b of the insulating film 23 lining the trench 86. By changing the shape of the trench 86, the shape of the second portion 33 of the gate wiring 30 embedded in the trench 86 may be changed.

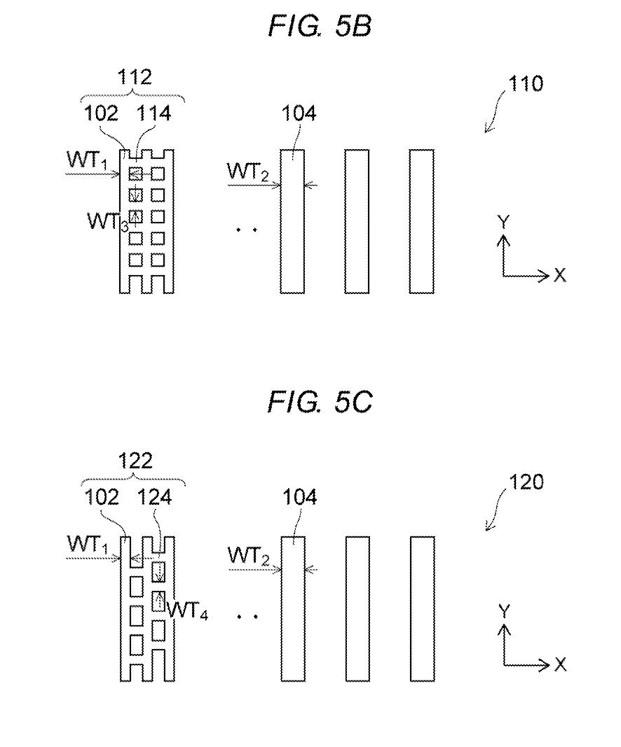

FIGS. 5A to 5C are plan views illustrating mask patterns 100, 110, 120 used to form the trench 84 and the trench 86.

The mask pattern 100 illustrated in FIG. 5A has a stripe pattern 102 extending in the Y-direction and a stripe pattern 104 extending in the Y direction. The stripe pattern 102 is used to etch the trenches 86. The stripe pattern 104 is used to etch the trenches 84. The stripe pattern 102 and the stripe pattern 104 are disposed in parallel to one another in the X-direction, respectively. The width (WT₁) in the X direction of the stripe pattern 102 is narrower than the width (WT₂) in the X direction of the stripe pattern 104.

The mask pattern 110 illustrated in FIG. 5B has the stripe pattern 104 for etching the trenches for the gate electrodes 20 and a grid mesh pattern 112 for etching the trenches 86 for the wiring 33. The mesh pattern 112 has a stripe pattern 102 extending in the Y direction as was the case in FIG. 5A, and also a stripe pattern 114 extending in the X direction. The stripe pattern 102 and the stripe pattern 114 intersect to form a grid. The width (WT₃) in the Y direction of the individual stripes of the stripe pattern 114 is narrower than the width (WT₂) in the X direction of the individual stripes of the stripe pattern 104.

The mask pattern 120 illustrated in FIG. 5C has the stripe pattern 104 and an offset mesh pattern 122. The offset mesh pattern 122 is used to form the trenches 86. The offset mesh pattern 122 has a stripe pattern 102 and a stripe pattern 124 extending in the X direction. The stripes of the stripe pattern 124 are provided on both sides of the middle stripe of the stripe pattern 102. One stripe of stripe pattern 124 is provided on one side of the stripe pattern 102, and another stripe of stripe pattern 124 provided on the other side thereof is shifted in the Y direction. The width (WT₄) in the Y direction of the stripes of the stripe pattern 124 are narrower than the width (WT₂) in the X direction of the stripes of the stripe pattern 104.

In the semiconductor device 1 according to the embodiment, a portion of the gate wiring 30 is formed to extend inwardly of the semiconductor layer 10. Thus, it is possible to narrow the width (W_{C}) of the gate wiring 30 without increasing the resistance of the wiring. As a result, it is possible to reduce a surface area of a device substrate on which the wiring region is located (i.e., the area of the chip dedicated to the wiring) and maintain an adequately low wiring resistance by extending the wiring cross section inwardly of the semiconductor layer 10, and thereby increase the area of the element region of the device without increasing the size of the device. In addition, it is possible to reduce the on-resistance of the semiconductor device 1.

Further, by utilizing the micro-loading effect, it is possible to form the second portion 33 of the gate wiring 30 such that the depth in the −Z direction thereof is shallower than the depth in the −Z direction of the gate electrode 20 using a single etch step to etch the polysilicon (or other conductive material) ultimately forming the gate electrodes 20 and the gate wiring 30. Thus, the gate electrode 20 and the gate wiring 30 may be simultaneously defined from a polysilicon layer. Therefore, the second portion 33 of the gate wiring 30 may be formed without increasing the number of manufacturing processes. In addition, by forming the p-type base layer 15 such that it extends deeper within the semiconductor layer than the lower end 33a of the second portion 33 of the gate wiring 30, and thereby maintain the gate wiring 30 within the p-type base layer 15, it is possible to prevent an increase in gate to drain capacitance of the resulting device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor layer having a first surface and a second surface opposed to the first surface;
a control electrode located on the second surface of the semiconductor layer; and
a conductor located on the second surface, and comprising a first portion provided on the second surface and at least one second portion extending from the first portion into the semiconductor layer.

2. The semiconductor device according to claim 1, wherein the semiconductor layer comprises:
a first sub layer of a first conductivity type, and
a second sub layer of a second conductivity type other than the first conductivity type, located on the first layer,
wherein the control electrode extends through the second sub layer and into the first sub layer.

3. The semiconductor device according to claim 2,
wherein the second portion of the conductor extends inwardly of, and terminates within, the second sub layer, and
wherein a width of the second portion of the conductor in a direction parallel to the second surface of the second portion is narrower than a width of the control electrode in a direction parallel to the second surface.

4. The semiconductor device according to claim 2, wherein the semiconductor layer further comprises a third semiconductor sub layer, of the first conductivity type, disposed on the second semiconductor sub layer and interposed between adjacent control electrodes.

5. The semiconductor device according to claim 1,
wherein the second portion of the conductor extends inwardly of the second surface along the same direction that the first portion of the conductor extends on the second surface.

6. The semiconductor device according to claim 5,
wherein the conductor includes a plurality of third portions, and
wherein the third portions are disposed parallel to a direction perpendicular to a direction that the first portion of the conductor extends on the second surface.

7. The semiconductor device according to claim 1,
wherein the second and third portions are provided in a grid pattern.

8. A method of manufacturing a semiconductor device, comprising:
forming a first semiconductor layer of a first conductivity type;
forming, on the first semiconductor layer, a second semiconductor layer of a second conductivity type;
forming a patterned etch mask over the second semiconductor layer, the patterned etch mask including a plurality of first openings therethrough having a first width, and a plurality of second openings therethrough having a second width smaller than the first width;
simultaneously etching, through the patterned mask openings, a plurality of first trenches having a first width, and a plurality of wiring trenches having a second width which is less than the first width, wherein the first trenches extend through the second semiconductor layer and into the first semiconductor layer, and the second trenches extend inwardly of, and terminate within, the second semiconductor layer;
depositing an insulative lining layer on the walls of the first and second trenches; and
depositing a conductor in the first and second trenches.

9. The method of claim 8, wherein while depositing a conductor in the first and second trenches, the conductor is also deposited on the surface of the second semiconductor layer adjacent the trenches, the method further comprising;
pattern etching the portion of the conductor on the second semiconductor layer and isolating a conductive wiring layer over the second trenches.

10. The method of claim 9, further comprising:
while pattern etching the portion of the conductor on the second semiconductor layer and isolating a conductive wiring layer over the second trenches, etching the conductor in the first trenches inwardly of the first layer.

11. The method of claim 10, further comprising:
depositing an interlayer dielectric layer on the conductor in the first trenches; and
pattern etching the interlayer dielectric layer to form individual interlayer dielectric regions extending from the location of the conductor in the first trenches to a location spaced from the second semiconductor layer.

12. The method of claim 11, further comprising:
forming a second conductor over the interlayer dielectric layer and the adjacent second semiconductor layer.

13. The method of claim 8, further comprising:
providing a plurality of third openings through the mask layer, the third openings extending between adjacent second openings, to form a grid pattern in the patterned mask; and
etching trenches in the pattern of the grid pattern inwardly of the, and terminating within, the second semiconductor layer.

14. The method of claim 13, wherein at least two third openings extend on either side of a second opening and form a continuous opening across the second opening.

15. The method of claim 13, wherein at least one third opening intersect a second opening at a first location, and a second third opening intersects the second opening in a location offset to the location where the at least one third opening intersects the second opening, the at least one and the second third openings extending parallel and offset to one another.

16. A semiconductor device comprising:
a first semiconductor layer of a first conductivity type;
a second semiconductor layer of a second conductivity type overlying the first semiconductor layer of the first conductivity type;
a plurality of first trenches extending parallel to one another and inwardly of the second semiconductor layer and terminating in the second semiconductor layer;
a plurality of second trenches extending parallel to one another and through the second semiconductor layer and terminating in the first semiconductor layer;
a first insulating layer disposed on the surface of the second semiconductor layer and along the surface of the first and second trenches; and
a conductor extending inwardly of each of the first and second trenches over the insulating layer, the conductor in the first trenches electrically connected to the conductor in the second trenches.

17. The semiconductor device of claim 16, further comprising:
a first electrode overlying the insulating layer and in contact with the conductor in the first trenches.

18. The semiconductor device of claim 16, further comprising:
a third semiconductor layer overlying the second semiconductor layer between adjacent second trenches.

19. The semiconductor device of claim 17, further comprising:
a second insulating layer overlying the conductor in the second trench.

20. The semiconductor device of claim 19, further comprising a second electrode overlying the second insulating layer.
